(19) United States
(12) Patent Application Publication
(10) Pub. No.: US 2023/0333166 A1
(43) Pub. Date: Oct. 19, 2023

(54) BATTERY LIFE PREDICTIONS USING MACHINE LEARNING MODELS

(71) Applicant: Hewlett-Packard Development Company, L.P., Spring, TX (US)

(72) Inventors: Divyansh Jindal, Pune (IN); Narendra Kumar Chincholikar, Pune (IN); Ravindra Ramtekkar, Pune (IN)

(73) Assignee: Hewlett-Packard Development Company, L.P., Spring, TX (US)

(21) Appl. No.: 18/042,863

(22) PCT Filed: Aug. 27, 2021
(86) PCT No.: PCT/US2021/048022

§ 371 Date: Feb. 24, 2023

(30) Foreign Application Priority Data
Aug. 30, 2020 (IN) 202041037353

(51) Int. Cl. G01R 31/367; G06N 5/025; G01R 31/392

(52) U.S. Cl. CPC G01R 31/367; G06N 5/025; G01R 31/392

(57) ABSTRACT

A server may include a receiving unit to obtain a set of battery attributes associated with a battery of a client device and a prediction unit to predict a battery condition by applying at least one first machine learning model to the set of battery attributes. The battery condition may include battery swelling, battery memory effect, battery performance degradation, or any combination thereof. Further, the server may include a recommendation unit to apply a second machine learning model to the predicted battery condition to predict a remaining life of the battery and recommend an action to be performed based on the predicted remaining life of the battery.

### BACKGROUND

Electronic devices such as laptops, cellular phones, tablets, and the like may have to operate at locations where alternating current (AC) power may be unavailable. In such cases, rechargeable batteries such as nickel cadmium (NiCad), nickel metal hydride (NiMH), lithium ion (Li-ion), and the like may be used as an alternative source of power, which are capable of providing power to the electronic devices. Further, a lifetime of such rechargeable batteries may depend on factors such as a battery type (e.g., NiCad, NiMH, or Li-ion), a number of charge/discharge cycles of the batteries, age of the batteries, and the like.

### BRIEF DESCRIPTION OF THE DRAWINGS

Examples are described in the following detailed description and in reference to the drawings, in which:

FIG. 1 is a block diagram of an example server, including a recommendation unit to predict a remaining life of a battery and recommend an action based on the predicted remaining life;

FIG. 2 is a block diagram of an example server including non-transitory machine-readable storage medium storing instructions to predict a remaining life of a battery;

FIG. 3 is an example sequence diagram, illustrating predicting a remaining life of a battery and generating a recommendation based on the predicted remaining life;

FIG. 4 is a block diagram of an example server including non-transitory machine-readable storage medium storing instructions to build a first set of machine learning models and a second machine learning model;

FIG. 5A is a schematic diagram of an example process for training a first set of machine learning models to predict battery swelling, battery memory effect, and battery performance;

FIG. 5B is a table depicting example battery attributes corresponding to a swelling prediction model;

FIG. 5C is a table depicting example benchmarking data corresponding to the swelling prediction model;

FIG. 5D is a table depicting example battery attributes corresponding to a memory prediction model;

FIG. 5E is a table depicting example benchmarking data corresponding to a performance prediction model;

FIG. 6A is a schematic diagram of an example process for predicting a remaining life of a battery and generate a recommendation based on the predicted battery swelling, battery memory effect, and battery performance;

FIG. 6B is a table depicting example device profiling data corresponding to the recommendation unit; and

FIG. 6C is a table depicting example recommendations corresponding to different client devices.

### DETAILED DESCRIPTION

Rechargeable batteries may be used in electronic devices such as laptops, tablets, cellular phones, or the like to provide mobile power and/or backup power. The rechargeable batteries may store an electric charge, which can be gradually released to power the electronic devices. Some rechargeable batteries may be charged using quick charging, trickle charging, and the like, which may impact a lifespan of the rechargeable batteries. Further, the rechargeable batteries may have a limited number of charge/discharge cycles and the batteries may charge and discharge within the limit. However, the charge holding capacity of the rechargeable batteries may degrade over time, resulting in a battery performance degradation.

Further, the rechargeable batteries may be susceptible to battery memory effect. The battery memory effect may cause the rechargeable batteries to hold a less charge due to degradation of the charge holding capacity over time. The battery memory effect may arise when the rechargeable batteries gradually lose a maximum energy capacity when the rechargeable batteries are repeatedly recharged after being partially discharged. In this case, the rechargeable batteries may appear to remember a smaller charge holding capacity. Thus, the battery memory effect may cause reduction in a longevity of the rechargeable battery's charge.

In some examples, improper charging or non-optimal charging patterns may adversely affect the lifespan of the rechargeable batteries. For example, fully discharging nickel-cadmium batteries may minimize battery memory effects within a rechargeable battery, whereas fully discharging a nickel metal-hydride rechargeable battery or a lithium-ion rechargeable battery may induce stresses that can damage the rechargeable battery.

In other examples, heat may be another environmental factor that may be detrimental to the lifespan of the rechargeable batteries. The source of heat that affects the rechargeable battery may be internally generated due to intensive usage of the electronic device, a battery charger that continues to trickle charge the rechargeable battery once the rechargeable battery has been charged to a maximum capacity (e.g., 100%), charging the rechargeable battery at a normal rate when the electronic device is exposed to a higher ambient temperature, or the like. Further, charging the rechargeable battery at a voltage higher than a voltage rating of the rechargeable battery can also adversely affect the lifespan of the rechargeable battery. In such instances, the rechargeable battery may undergo swelling due to thermal impact and chemical reactions between gases, which can cause hazardous impact. Further, the chemical reactions between gases may result in a deformation of the battery dimensions. Thus, the life span of the rechargeable batteries may depend on battery performance degradation, battery memory effect, battery swelling, and/or the like.

Examples described herein may utilize machine learning models to predict an expected or remaining life of a rechargeable battery and/or a probability of swelling associated with the rechargeable battery. Further, examples described herein may recommend actions based on the predicted remaining life of the rechargeable battery to enhance a lifespan of the rechargeable battery, minimize swelling of the rechargeable battery, obtain a maximum power from the rechargeable battery during every charge/discharge cycle, or the like.

Examples described herein may provide a server that is communicatively coupled to a client device, for instance, via a network. The server may obtain a set of battery attributes associated with a battery of the client device. Further, the server may predict a battery condition by applying at least one first machine learning model to the set of battery attributes. The battery condition may include battery swelling, battery memory effect, battery performance degradation, or any combination thereof. For example, different machine learning models can be applied to different subsets of the set of battery attributes to predict the battery swelling, battery memory effect, and battery performance degradation.

Furthermore, the server may apply a second machine learning model to the predicted battery condition to predict a remaining life of the rechargeable battery and recommend an action to be performed based on the predicted remaining life of the rechargeable battery. Example recommended action may include a remedy to enhance the rechargeable battery life, a replacement/upgradation of the rechargeable battery, or the like based on the predicted remaining life of the rechargeable battery.

In the following description, for purposes of explanation, numerous specific details are set forth in order to provide a thorough understanding of the present techniques. However, the example apparatuses, devices, and systems, may be practiced without these specific details. Reference in the specification to “an example” or similar language means that a particular feature, structure, or characteristic described may be included in at least that one example but may not be in other examples.

The terms “rechargeable battery” and “battery” are used interchangeably throughout the document and may refer to a type of electrical battery that can be repeatedly charged and discharged. The rechargeable battery may store electrical energy using electrochemical cells. The electrochemical cells can be restored to full or near full charge by the application of the electrical energy. Example battery may be a smart battery having a circuitry to determine and communicate information/data related to a condition of the battery to an external circuit (e.g., a computing device).

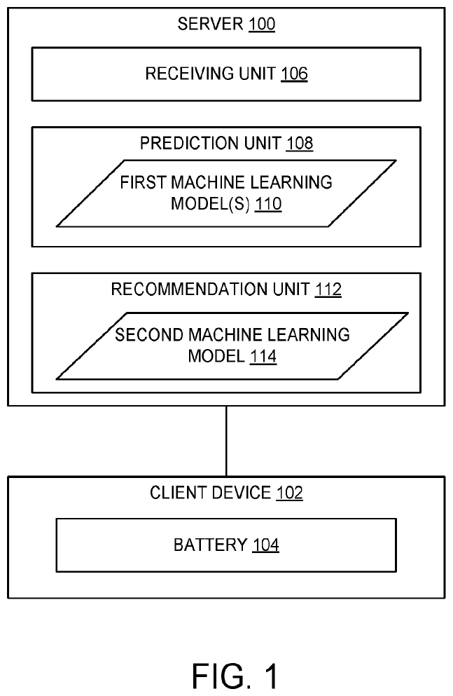

Turning now to the figures, FIG. 1 is a block diagram of an example server 100, including a recommendation unit 112 to predict a remaining life of a battery 104 and recommend an action based on the predicted remaining life. As shown in FIG. 1, server 100 may be communicatively coupled to a client device 102 via a network. Example network may be a local area network (LAN), a wide area network (WAN), the Internet, a wired connection, and/or the like. Example client device 102 may be a laptop, a smartphone, a personal digital assistant (PDA), or any other device which can operate on battery power of battery 104. Example battery 104 may include nickel cadmium (NiCad), nickel metal hydride (NiMH), lithium ion (Li-ion), or the like. Example server 100 may be a computing device having a processor and a memory to store instructions to perform functions of a receiving unit 106, a prediction unit 108, and recommendation unit 112.

In an example, server 100 may include receiving unit 106 to obtain a set of battery attributes associated with battery 104 of client device 102. For example, the battery attributes may include a battery temperature, a battery design capacity, a full charge battery capacity, a mean battery cycle, an amount of time client device 102 is on battery, a mean processor utilization, a mean memory utilization, a voltage for each cell in the battery, and/or the like.

Further, server 100 may include prediction unit 108 to predict a battery condition by applying at least one first machine learning model 110 to the set of battery attributes. In an example, the battery condition may include battery swelling, battery memory effect, battery performance degradation, or any combination thereof. For example, the battery memory effect (e.g., also referred to as a battery effect, a lazy battery effect, or a battery memory) may be an effect observed in battery 104 that can cause battery 104 to hold less charge. The battery memory effect may arise when battery 104 gradually lose a maximum energy capacity when battery 104 is repeatedly recharged after being partially discharged. Further, battery swelling may be caused due to an overcharge of battery 104. The overcharge of battery 104 may cause a chemical reaction, resulting in a release of heat and gases that can expand inside battery 104, which in turn causes battery 104 to swell or even to split open. The battery performance degradation may occur over time and cause a reduction in an amount of energy battery 104 can store, an amount of power battery 104 can deliver, or the like.

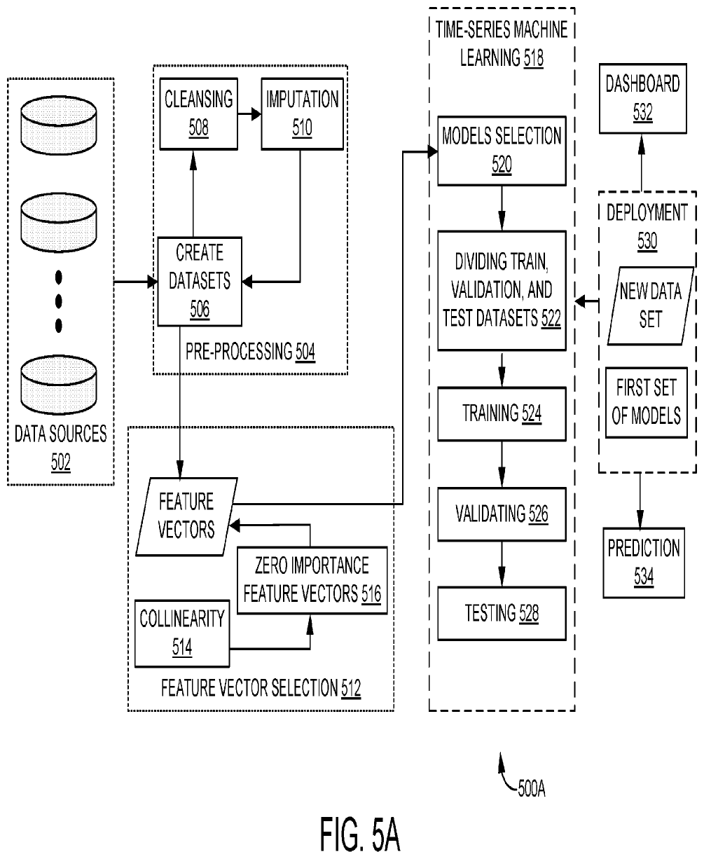

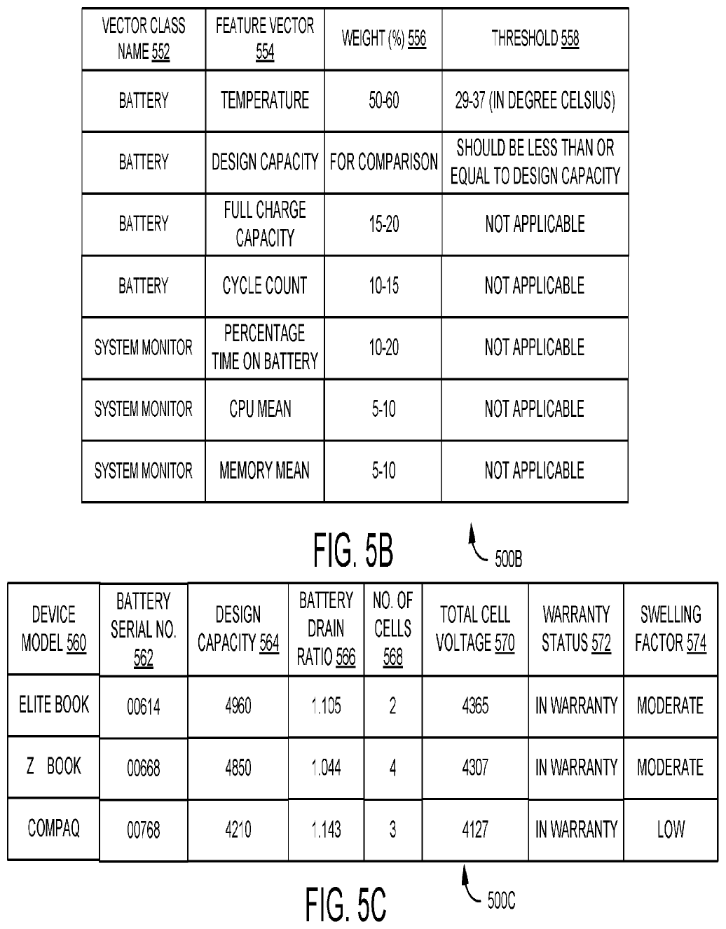

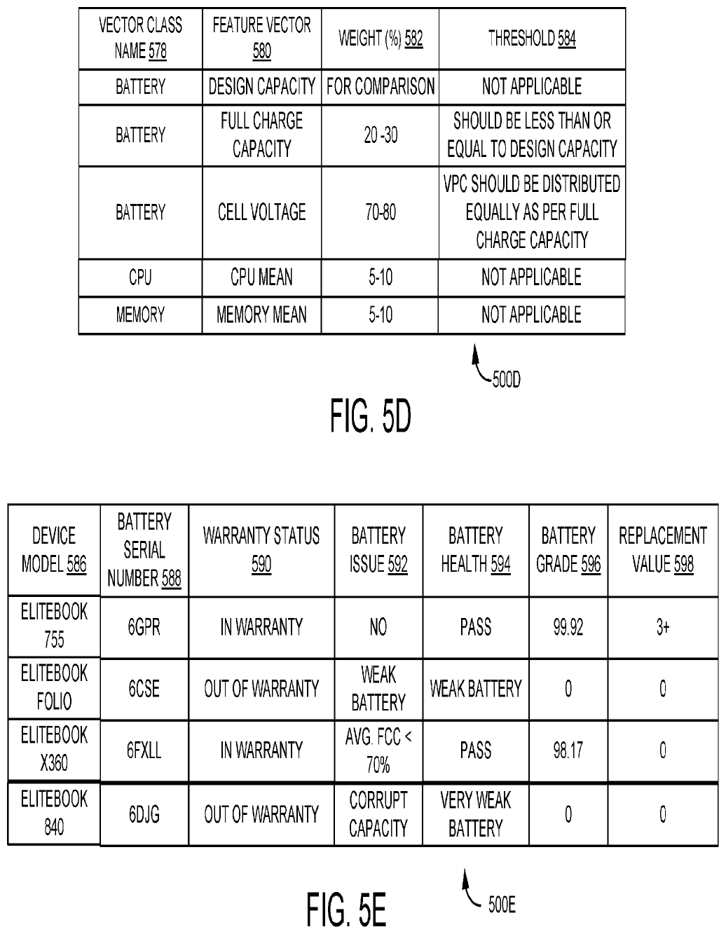

In an example, first machine learning model(s) 110 may be trained on input data using machine learning and data mining methods to predict the battery swelling, battery memory effect, and/or battery performance degradation. The input data may be selected from a set of time-series historical battery attributes associated with a plurality of batteries. For example, machine learning may refer to an application of artificial intelligence (AI) that provides systems an ability to automatically learn and improve from experience without being explicitly programmed. Example training of machine learning model(s) 110 is described in FIG. 5A.

Furthermore, server 100 may include recommendation unit 112 to apply a second machine learning model 114 to the predicted battery condition to predict a remaining life of battery 104. Example first machine learning model(s) 110 and second machine learning model 114 may be supervised machine learning models (e.g., random forest classifiers, recurrent neural networks, long short-term memory (LSTM) models, and/or the like). In supervised machine learning, first machine learning model(s) 110 and second machine learning model 114 may be trained using labelled training data, i.e., input data (e.g., time-series historical battery attributes) and associated output data (i.e., battery conditions and remaining battery life predictions). In an example, recommendation unit 112 may
retrieve device information (e.g., a type of battery 104, battery identifier, client device identifier, CPU utilization, memory utilization, or the like) associated with client device 102;
retrieve a domain expert feed corresponding to battery 104 from a knowledge base; and
predict the remaining life of battery 104 by applying second machine learning model 114 to the device information, the predicted battery condition, and the domain expert feed.

Further, recommendation unit 112 may apply second machine learning model 114 to the predicted battery condition to recommend an action to be performed based on the predicted remaining life of battery 104. In an example, the recommended action may include a remedy to manage a lifecycle, a swell rate, and/or a runtime of the battery based on the predicted remaining life. For example, the recommended action may be to turnoff keyboard light or screen light when client device 102 is not in use, adjust screen brightness based on room conditions, or the like. In such examples, the recommended action can be applied with or without manual intervention. In another example, the recommended action may include a replacement or upgradation of battery 104 based on the predicted remaining life. For example, the recommended action may include an indication to upgrade battery 104 with 6 battery cells, 8 battery cells, or the like based on device profiling data (e.g., processor utilization data, memory utilization data, type of applications running, or the like).

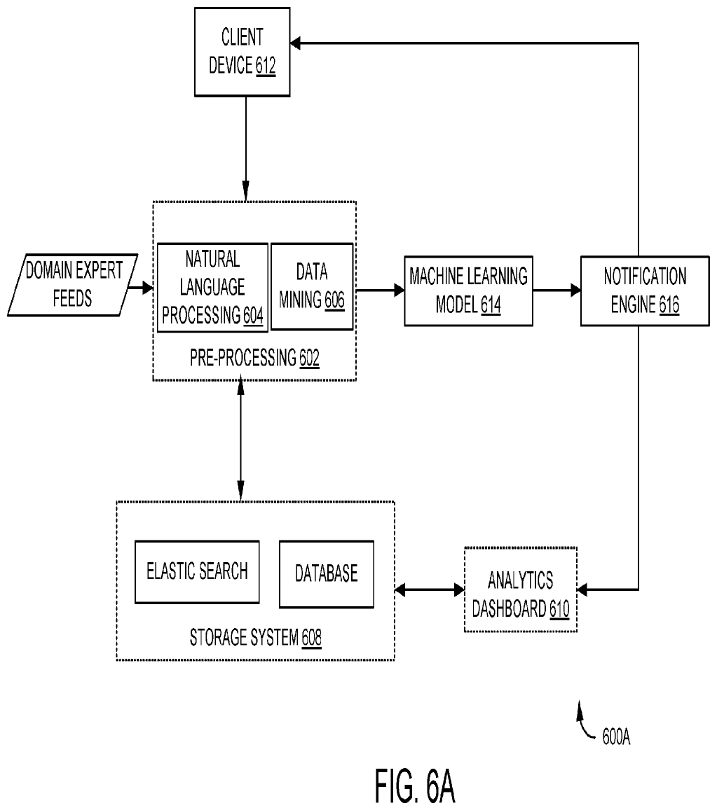

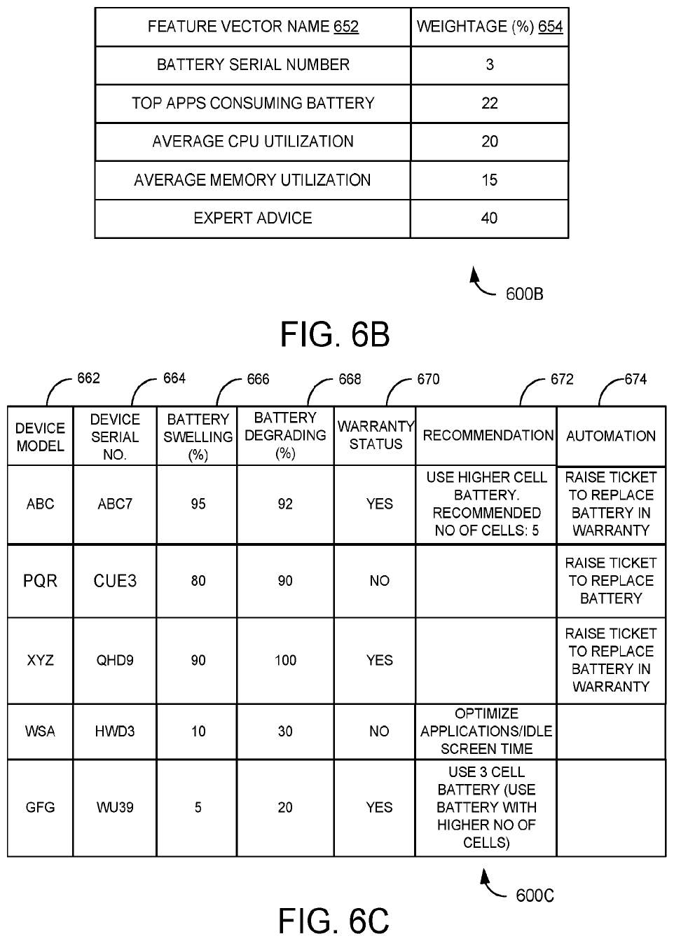

In other examples, recommendation unit 112 may generate an analytical report, on a dashboard of a user interface, including a visualization of analytic or summary information related to the battery swelling, battery memory effect, battery performance degradation, remaining life of the battery, an expected battery life based on the recommend action, or any combination thereof. For example, the analytical report may be presented in the form of a graph, pie chart, or the like. Example recommendation unit is described in FIG. 6A.

In some examples, the functionalities described herein, in relation to instructions to implement functions of receiving unit 106, prediction unit 108, recommendation unit 112, and any additional instructions described herein in relation to the storage medium, may be implemented as engines or modules including any combination of hardware and programming to implement the functionalities of the modules or engines described herein. The functions of receiving unit 106, prediction unit 108, and recommendation unit 112 may also be implemented by a processor. In examples described herein, processor may include, for example, one processor or multiple processors included in a single device or distributed across multiple devices.

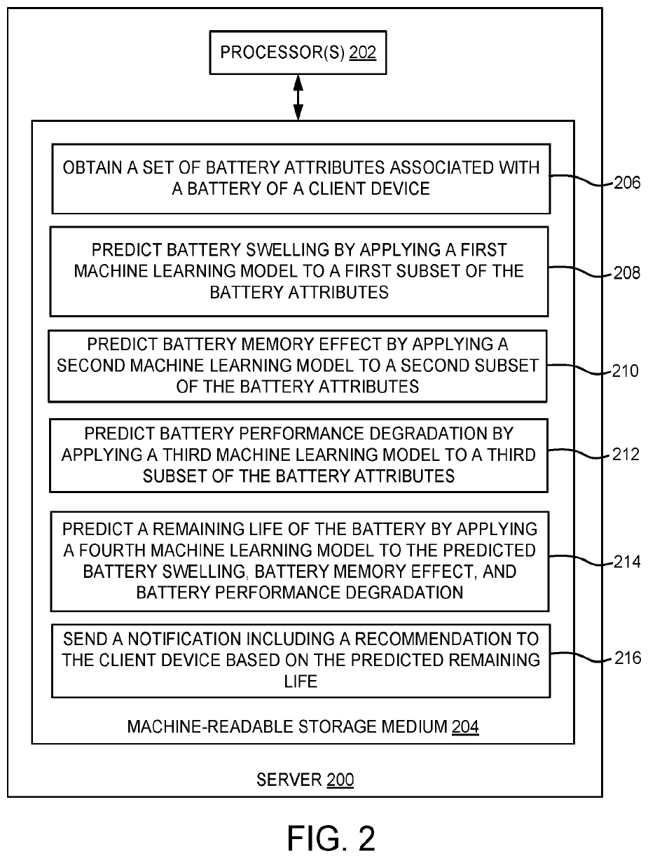

FIG. 2 is a block diagram of an example server 200 including non-transitory machine-readable storage medium 204 storing instructions (e.g., 206 to 216) to predict a remaining life of a battery. Server 200 may include a processor 202 and machine-readable storage medium 204 communicatively coupled through a system bus. Processor 202 may be any type of central processing unit (CPU), microprocessor, or processing logic that interprets and executes machine-readable instructions stored in machine-readable storage medium 204.

Machine-readable storage medium 204 may be a random-access memory (RAM) or another type of dynamic storage device that may store information and machine-readable instructions that may be executed by processor 202. For example, machine-readable storage medium 204 may be synchronous DRAM (SDRAM), double data rate (DDR), rambus DRAM (RDRAM), rambus RAM, etc., or storage memory media such as a floppy disk, a hard disk, a CD-ROM, a DVD, a pen drive, and the like. In an example, machine-readable storage medium 204 may be non-transitory machine-readable medium. Machine-readable storage medium 204 may be remote but accessible to server 200.

As shown in FIG. 2, machine-readable storage medium 204 may store instructions 206-216. In an example, instructions 206-216 may be executed by processor 202 to predict a remaining life of a battery. Instructions 206 may be executed by processor 202 to obtain a set of battery attributes associated with a battery of a client device. In an example, the set of battery attributes may be classified into a first subset, a second subset, and a third subset based on properties and/or characteristics of the battery attributes.

Instructions 208 may be executed by processor 202 to predict battery swelling by applying a first machine learning model to the first subset of the battery attributes. Instructions 210 may be executed by processor 202 to predict battery memory effect by applying a second machine learning model to the second subset of the battery attributes. Instructions 212 may be executed by processor 202 to predict battery performance degradation by applying a third machine learning model to the third subset of the battery attributes. In an example, the first machine learning model, the second machine learning model, and the third machine learning model may be trained on input data using machine learning and data mining methods to predict battery swelling, battery memory effect, and battery performance degradation, respectively. Example input data may be selected from a set of time-series historical battery attributes associated with a plurality of batteries.

In an example, instructions to predict the battery swelling, the battery memory effect, and the battery performance degradation may include instructions to:
extract at least one first feature vector, at least one second feature vector, and at least one third feature vector from the first subset, the second subset, and the third subset, respectively,
assign a weightage to each of the first feature vector(s), second feature vector(s), and third feature vector(s), and
predict the battery swelling, the battery memory effect, and the battery performance degradation by inputting the at least one first feature vector, at least one second feature vector, and at least one third feature vector along with associated weightage into the first machine learning model, second machine learning model, and third machine learning model, respectively.

In some examples, a threshold value may also be applied to the first feature vector(s), second feature vector(s), and/or third feature vector(s) in addition to the weightage. The feature vectors may be either directly selected from the battery attributes or derived/calculated from the battery attributes. Further, the battery swelling, battery memory effect, and battery performance degradation may be predicted based on benchmark data corresponding to the first machine learning model, second machine learning model, and third machine learning model.

Instructions 214 may be executed by processor 202 to predict a remaining life of the battery by applying a fourth machine learning model to the predicted battery swelling, battery memory effect, and battery performance degradation. In an example, the fourth machine learning model may be trained on input data using the machine learning and the data mining methods to predict remaining life of the battery. Example input data may include the battery swelling, the battery memory effect, and the battery performance degradation predicted using the time-series historical battery attributes, device information (e.g., device models, battery types, device profiling information) associated with the plurality of batteries, and domain expert feeds.

In an example, instructions to predict the remaining life of the battery may include instructions to:
extract a feature vector by combining the predicted battery swelling, the predicted battery memory effect, and the predicted battery performance degradation, and
predict the remaining life of the battery by inputting the feature vector, a domain expert feed, and device information of the client device into the fourth machine learning model.

Instructions 216 may be executed by processor 202 to send a notification including a recommendation to the client device based on the predicted remaining life. Example recommendation may include a remedy to enhance the life of the rechargeable battery, a replacement/upgradation of the rechargeable battery, or the like.

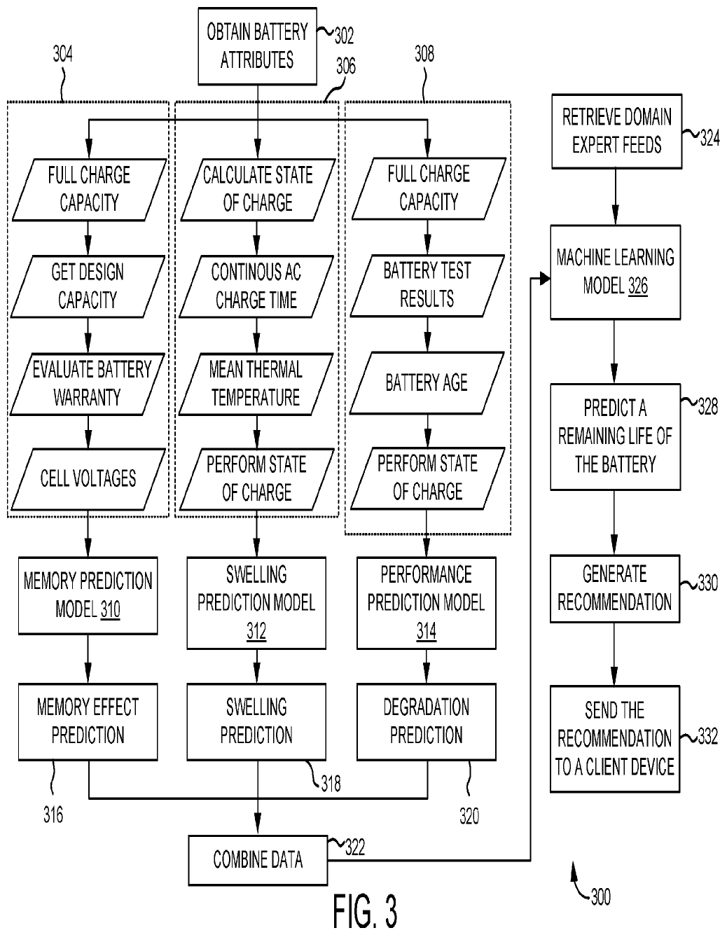

FIG. 3 is an example sequence diagram 300, illustrating predicting a remaining life of a battery and generating a recommendation based on the predicted remaining life. At 302, battery attributes associated with a battery of a client device may be obtained. Further, the battery attributes may be grouped or classified into different subsets (e.g., 304, 306, and 308) based on properties and/or characteristics of the battery attributes. Further, feature vectors may be selected/derived from the subsets 304, 306, and 308 and the selected/derived feature vectors may be fed into different machine learning models (e.g., a memory prediction model 310, a swelling prediction model 312, and a performance prediction model 314).

At 316, memory prediction model 310 may predict battery memory effect of the battery using feature vectors, for instance, as shown in subset 304. Example feature vectors may include a battery voltage, a design voltage, a capacity of the battery in terms of voltage, a number of cells in the battery, individual cell voltage, and the like. The feature vectors may be fed to memory prediction model 310 to predict the battery memory effect. In some example, clusters of different client devices (e.g., different models of client devices) having substantially similar configurations may be simultaneously monitored for predicting the battery memory effect, however, prediction of remaining life and associated recommendations can be sent to individual client devices.

At 318, swelling prediction model 312 may predict swelling of the battery using feature vectors, for instance, as shown in subset 306. For example, features such as a battery drain ratio (e.g., calculated from battery design capacity and battery full capacity), mean thermal temperature, state of charge, and the like may be selected/determined and fed to swelling prediction model 312 to predict the battery swelling. For example, when the client device has a battery drain ratio of less than 1, then the battery may be categorized as being in a swelling condition, where a user may have to replace the battery. In other examples, a temperature threshold of the battery can be considered for predicting the swelling prediction. In this example, consider that the temperature threshold may be defined between 28-37 degree Celsius, for instance. Based on an operating temperature of the client device and the temperature threshold, the battery swelling may be predicted by swelling prediction model 312. The battery attributes can be continuously obtained and analyzed using swelling prediction model 312 to predict the battery swelling.

At 320, performance prediction model 314 may predict performance degradation of the battery using feature vectors, for instance, as shown in subset 308. For example, to predict the performance degradation of the battery, a battery grade may be determined based on the feature vectors, for instance, shown in subset 308 (e.g., battery full charge capacity, battery age, and the like). Further, based on the battery grade, a battery replacement score (e.g., 0, 1, 2, 3, 3+, or the like), a battery replacement issue, and a battery health may be determined. The battery health may indicate a health status of the battery (e.g., whether the battery is healthy or non-healthy) along with summary information. Thus, the performance degradation of the battery can be predicted using performance prediction model 314. Further, analytical reports may also be generated based on the computations performed on the battery attributes of different client devices for calculating the battery grade and/or battery replacement score. The analytical reports indicating the battery health status of the client device may be presented to the user.

At 322, the predicted battery condition (e.g., the battery memory effect prediction, the swelling prediction, and the performance degradation prediction) from multiple models (e.g., memory prediction model 310, swelling prediction model 312, and performance prediction model 314) may be combined to form a single vector feed and the single vector feed may be inputted to another machine learning model 326. At 324, domain expert feeds may be retrieved from a knowledge database and fed into machine learning model 326 to derive the inference about a condition of the battery. In other examples, device information including device profiling data from a device profiling service such as central processing unit (CPU) utilization, memory utilization, application consuming the CPU and memory, and the like may be fed to machine learning model 326.

At 328, machine learning model 326 may predict a remaining life of the battery using the inputted battery condition, the domain expert feeds, and device profiling data. In one example, machine learning model 326 may predict a number of days in which the swelling effect can occur in the battery (e.g., the battery can experience battery swelling in ‘x’ days as per the current use of the client device), a functionality of a battery cell (e.g., whether battery cells are functioning correctly), a performance deformation of battery cell (e.g., voltage of the battery cell degraded to 0), an expected time to upgrade the battery with a higher number of cells (e.g., based on the battery usage), an amount of load each battery cell has to put for functioning (e.g., based on a standard battery operating time after full charge to the time the battery is operating), and the like. In yet another example, based on the battery performance degradation, a prediction such as “the battery is degrading at x percentage and will be completely degraded in y days as per the current battery consumption” may be made.

At 330, a recommendation may be generated based on the predicted remaining life. At 332, the recommendation may be sent to the client device. For example, the recommendation may include an action to be performed to enhance battery life or a suggestion to replace/upgrade the battery. For example, the recommended action can be, but not limited to:
use of a smart charger that can stop charging after 100%.
update basic input/output system (BIOS) software on the client device.
recommendation for using a smart charger.
turnoff keyboard light when the client device is not in use.
turnoff screen light when the client device is not in use.
adjust screen brightness based on room conditions.

In an example, the recommendation may include a suggestion to change or upgrade the battery when above mentioned recommendation action may not be able to enhance the battery life. For example, consider a client device having a battery of 4 cells and a game installed therein may consume a significant amount of resources such as CPU and memory. In this case, due to increase in the resource consumption, the battery performance and/or life may get affected. For example, the battery performance may get affected due to a CPU fan utilizing an increased power, an increased memory utilization, multiple read/writes to disk involving high power consumption, and the like. In such examples, a recommendation may be sent to the user to increase the battery cells (e.g., to use 6 or 7 cell battery instead of 4 cell battery) to enhance the battery life.

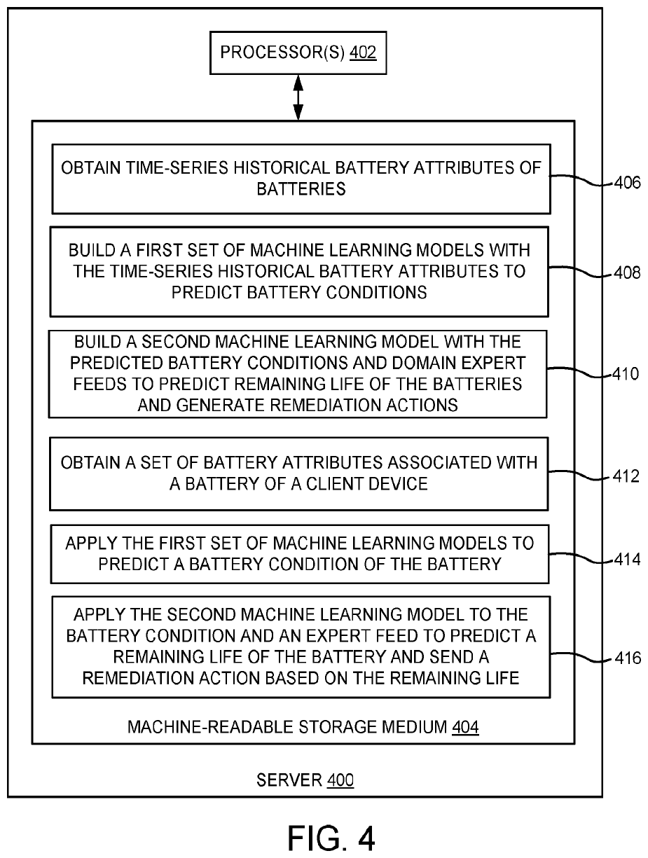

FIG. 4 is a block diagram of an example server 400 including non-transitory machine-readable storage medium 404 storing instructions (e.g., 406 to 416) to build a first set of machine learning models and a second machine learning model. Server 400 may include a processor 402 and machine-readable storage medium 404 communicatively coupled through a system bus. Processor 402 may be any type of central processing unit (CPU), microprocessor, or processing logic that interprets and executes machine-readable instructions stored in machine-readable storage medium 404.

Machine-readable storage medium 404 may be a random-access memory (RAM) or another type of dynamic storage device that may store information and machine-readable instructions that may be executed by processor 402. For example, machine-readable storage medium 404 may be synchronous DRAM (SDRAM), double data rate (DDR), rambus DRAM (RDRAM), rambus RAM, etc., or storage memory media such as a floppy disk, a hard disk, a CD-ROM, a DVD, a pen drive, and the like. In an example, machine-readable storage medium 404 may be non-transitory machine-readable medium. Machine-readable storage medium 404 may be remote but accessible to server 400.

As shown in FIG. 4, machine-readable storage medium 404 may store instructions 406-416. In an example, instructions 406-416 may be executed by processor 402 to predict a remaining life of a battery. Instructions 406 may be executed by processor 402 to obtain time-series historical battery attributes of batteries, for instance, associated with various client devices. Further, machine-readable storage medium 404 may store instructions to:
create a dataset with a plurality of features based on the time-series historical battery attributes,
cleanse and/or impute the dataset, and
remove collinear and zero importance features from the cleansed and imputed dataset.

Instructions 408 may be executed by processor 402 to build a first set of machine learning models with the time-series historical battery attributes to predict battery conditions. Example battery conditions may include battery swelling, battery memory effect, and/or battery performance degradation. In an example, instructions to build the first set of machine learning models may include instructions to:
classify the time-series historical battery attributes into a first subset, a second subset, and a third subset based on properties and/or characteristics of the battery attributes,
train, validate, and test a swelling prediction model using the first subset to predict the battery swelling of the batteries,
train, validate, and test a memory prediction model using the second subset to predict the battery memory effect of the batteries, and
train, validate, and test a performance prediction model using the third subset to predict the battery performance degradation of the batteries.

For example, each of the first subset, second subset, and third subset may be divided into train dataset (e.g., 60%), validation dataset (e.g., 20%), and test dataset (20%). The train dataset may be used to train respective models. Validation data may be used to validate respective models. Before validation, the models may be tested with the respective test dataset. After training with the selected features, the models may be evaluated. During testing, when the resulting metrics are satisfactory (e.g., accuracy of the models is above a threshold), the models can be deployed for predicting with out-of-sample data (i.e., future data).

Instructions 410 may be executed by processor 402 to build a second machine learning model with the predicted battery conditions and domain expert feeds to predict remaining life of the batteries and generate remediation actions. In an example, instructions to build the second machine learning model may include instructions to train, validate, and test the second machine learning model using an outcome of the first set of machine learning models and the expert feeds to predict the remaining life of the batteries and generate the remediation actions.

Instructions 412 may be executed by processor 402 to obtain a set of battery attributes (i.e., out-of-sample data) associated with a battery of a client device. Instructions 414 may be executed by processor 402 to apply the first set of machine learning models to predict a battery condition of the battery. Instructions 416 may be executed by processor 402 to apply the second machine learning model to the battery condition and an expert feed to predict a remaining life of the battery and send a remediation action based on the remaining life.

FIG. 5A is a schematic diagram of an example process 500A for training a first set of machine learning models (e.g., such as the first set of models described in FIG. 4) to predict battery swelling, battery memory effect, and battery performance degradation. As shown in FIG. 5A, time-series historical battery attributes received from different data source(s) 502 may be pre-processed (e.g., at 504). For example, pre-processing the historical battery attributes may include creating datasets (e.g., at 506), cleansing the datasets (e.g., at 508), imputing the datasets (e.g., at 510), or any combination thereof. Example data sources may store information related to batteries, operating systems, battery monitors, processors, or any other components that affect battery performance.

In one example, cleansing the datasets may include detecting and replacing an outlier value of a variable in the historical battery attributes. In another example, cleansing the datasets may include normalizing a value of a variable in the historical battery attributes. Further, the datasets may be imputed for any missing data value, invalid data value, or scaling a data value in each dataset. In this example, missing or invalid data values can be processed to impute values to replace the missing or invalid data values. In other words, the datasets may be imputed to insert estimates for missing values that may have minimal impact on the analysis method regarding the values that are not missing. The datasets may be imputed through different statistical processes such as mean, previous entry, next entry, automated method (e.g., mice in R), and the like.

Further, a feature vector selection (e.g., at 512) may be performed on the pre-processed datasets. For example, the feature vector selection may be a result of distribution study of the feature vectors made over time, and comparison of the distributions (e.g., 30 days, 60 days, or the like) before the failure with the values in the batteries that may not have failed. Further, such feature vectors may be used in different machine learning models and the feature vectors of the best performing model may be selected to predict battery conditions. In one example, the pre-processed datasets may be filtered by selecting a set of feature vectors that are significant by statistical correlation. Further, a collinearity check may be performed to remove feature vectors that are colinear (e.g., at 514) and/or zero importance feature vectors (e.g., at 516).

At 518, the first set of machine learning models may be built with the time-series historical battery attributes to predict the battery conditions. The battery conditions may include battery swelling, battery memory effect, and/or battery performance degradation. In an example, the first set of machine learning models may be built with the cleansed and imputed datasets with the selected/updated feature vectors. In one example, generating the time-series machine learning model may include:
Selecting a first set of time-series machine learning models based on the battery conditions (e.g., at 520). Example machine learning models may include a random forest classifier, a recurrent neural network, a long short-term memory (LSTM) model, or the like.
Dividing the cleansed and imputed datasets with the selected feature vectors into train dataset, validation dataset, and test dataset, at 522.
Training the first set of time-series machine learning models with the training dataset, at 524.
Validating the first set of time-series machine learning models with the validation dataset, at 526. In one example, the first set of time-series machine learning models may be tuned based on the validation.
Testing the first set of time-series machine learning models with the test dataset, at 528.

At 530, the first set of trained and tested time-series machine learning models may be deployed to predict battery conditions. At 534, the first set of trained and tested time-series machine learning models may predict a battery condition with a new dataset (e.g., an out-of-sample dataset of a battery). Further, the predicted battery condition along with analytics summary and recommendations may be presented on a dashboard, at 532, for instance. Example factors considered for the swelling prediction model, the memory prediction model, and the degradation model to predict the battery conditions may be described below.

### Swelling Prediction Model

Since an exact date that the battery starts to swell may be unknown, a swelling period (e.g., 60 days) before a support call date may be defined and attributes/records within the swelling period may be used to analyze swollen batteries. For example, exploratory data analysis for the battery swelling may include:
Swollen batteries may have higher mean battery temperature.
Swollen batteries may have higher mean percent time on AC power.
Swollen batteries may have higher mean fan temperature.
Swollen batteries may have higher mean CPU utilization and memory utilization.
Swollen devices may have lower mean battery cycle count. Battery cycle may represent a count of a full charge for the battery.
Different device models may have different proportions of swelling.
The battery temperature may indicate a seasonality (e.g., a higher temperature during summer period).

Based on the above exploratory data analysis, one of a machine learning approach (e.g., a random forest classifier) and a forecasting approach may be implemented to predict the battery swelling. Example battery attributes including vector class name 552, feature vector 554, weight percentage 556, and corresponding threshold 558 as depicted in table 500B of FIG. 5B may be considered in the machine learning approach.

In the machine learning approach, precision, recall, accuracy, and F1 score of different machine learning models may be calculated and based on the calculation, a decision on which machine learning model to be used can be made,
where precision may be a number of true positive/(number of true positive+number of false positive),
recall may be a number of true positive/number of true positive+number of false negative), and
F1 may be a weighted average of precision and recall.

Further, a receiver operating characteristic (ROC) curve may be plotted for the changes on true positive and false positive under different thresholds, where a threshold may be a minimum probability that classify an observation as positive and a high threshold may be a high penalty on the false positive.

In the forecasting approach, the swelling prediction model may utilize rules for classifying the swollen batteries. Example rules may include:
Test the mean temperature difference between swollen and un-swollen batteries. For testing, the battery temperature records within the swelling period (i.e., 60 days) may be collected as sample data for swollen devices and the recent 60 days battery temperature records may be collected as sample data for un-swollen devices.
The mean battery temperature for swollen devices may be between 31.84 and 38.03 and the mean battery temperature for un-swollen devices may be between 24.62 and 24.68.
In the above example, the use of temperature <30 and >=25 may be considered as a rule.

In another example, a proportion test may be performed on the time-series historical battery data to identify feature vectors related to a percent time the client devices are on AC power. Since battery swelling is a persistent condition, time-based feature vectors such as the percent time on AC, the battery temperature during a specific period, and the like may be considered. Example benchmarking data to predict the battery swelling is depicted in table 500C of FIG. 5C. Table 500C may depict a device model 560, battery serial number 562, and battery attributes associated with battery serial number 562 such as design capacity 564, battery drain ratio 566, number of cells 568, cell voltage 570, warranty status 572, and the like. Also, table 500C may depict a swelling factor 574 corresponding to different values of battery attributes, which can be used as the benchmark data for predicting the battery swelling.

### Memory Prediction Model

A battery with battery memory effect can be revived to a maximum capacity when the battery is not damaged. To restore the battery memory, the memory prediction model may be trained to predict the battery memory effect and corresponding recommendation may be made based on:
A full charge capacity (FCC) of the battery as well as a number of cells present in the battery.
When the battery loses memory, then the FCC may reduce as well as the number of cells functioning may reduce.
Restoring the memory of the battery may be done in a series of steps:
   a. Number of cells that are actively functioning out of total number of cells in the battery may be calculated based on an FCC score.
   b. Discharge the battery to 1 volt per cell (VPC) and then fully charge the battery several times in a succession. The process of charging and discharging may be repeated until battery restores to the maximum charge capacity.
   c. To restore the maximum charge capacity, a rule may be employed based on the FCC score, the number of active cells, a total number of cells, a maximum charge capacity of the battery, and the like.

Example vector class name 578, feature vector 580, and corresponding weight percentage 582 and threshold 584 to predict the battery memory effect may be depicted in table 500D of FIG. 5D.

### Performance Prediction Model

The performance prediction model may predict when a battery can show up a fail-status or degraded-status within three months, for instance and therefore should be replaced. In an example, the performance prediction model may deliver a probability of failure or degradation of the battery, a failure type or a degraded status, a timespan for the failure or the degradation, or the like. The performance prediction model may predict the performance degradation based on the following rules:
When a service is marked as “replace now”, the battery may be marked and replaced.
Otherwise, a prediction may be made to predict when the battery will fail or degrade within the next 90 days.
Based on the prediction, a health grade of the battery may be calculated.
To predict the fail status, machine learning models such as a recurrent neural network, a long short-term memory (LSTM), or the like may be utilized.
Numerical times series-data may be collected from the battery. A battery failure may a sequence of problems, measurements, events, or the like. With this kind of neuronal network, a sequence factor may be determined to see the data in dependence of the timeline.
To predict a degraded status, an ensemble learning method (e.g., a random forest classifier) may be used for classification.

Example benchmarking data to predict the battery performance degradation may be depicted in table 500E of FIG. 5E. Table 500E may depict a device model 586, battery serial number 588, and warranty status 590. Also, table 500E may depict battery issue 592, battery health 594, battery grade 596, and corresponding replacement value 598, which can be used as the benchmark data for predicting the battery performance degradation.

FIG. 6A is a schematic diagram of an example recommendation unit 600A (e.g., such as recommendation unit 112 of FIG. 1) to predict a remaining life of a battery and generate a recommendation based on the predicted remaining life. For example, the second machine learning model may be trained, validated, and tested using an outcome of the first set of machine learning models (e.g., as described in FIG. 5A), device information associated with different models, and the expert feeds to predict the remaining life of the batteries and generate the remediation actions

Upon deployment of the second machine learning model after testing, recommendation unit 600A may receive device information including device profiling data from a client device 612. Further, recommendation unit 600A may retrieve a domain expert feed corresponding to a battery type from a knowledge base. Furthermore, recommendation unit 600A may retrieve predicted battery conditions (e.g., battery swelling, battery memory effect, the battery performance degradation) from a storage system 608 (e.g., including elastic search, database, and the like). The predicted battery conditions may be an outcome of the prediction models corresponding to the battery of the client device, for instance, as described in FIG. 5A.

At 602, the retrieved information may be pre-processed using natural language processing 604 and data mining 606 methods, for instance. Further, the pre-processed information may be fed to a machine learning model 614. In an example, machine learning model 614 may predict a remaining life of the battery based on the pre-processed information. Example pre-processed information may include feature vectors 652 and corresponding weightages 654 as depicted in table 600B of FIG. 6B.

Further, a notification engine 616 may generate a remediation action based on the predicted remaining life and send the recommendation to client device 612. Furthermore, notification engine 616 may generate and present analytics ports on analytics dashboard 610. For example, the remediation action may enhance or intact the life of the battery over a period. Table 600C of FIG. 6C may depict example recommendations (e.g., recommendation 672) generated (e.g., by recommendation unit 600) for different client devices (e.g., having a device model 662 and a corresponding device serial number 664).

In table 600C shown in FIG. 6C, two battery conditions (e.g., battery swelling 666 and battery degradation probability 668 in percentage) may facilitate to provide health of the battery. For example, battery swelling 666 as 80% may depict that the battery capacity has reached to 80% and the battery may stop functioning if the battery capacity exceeds a limit, and may also have an adverse effect on other components of client device 612. Further, the battery degradation percentage 668 may be a score calculated from a battery grade, lower the value of battery grade higher the battery degradation percentage.

In some examples, a recommendation 672 (e.g., to update a number of cells in the battery) may be generated to enhance the life of the battery based on battery conditions 666 and 668 and associated warranty status 670. In other examples, an automation 674 may depict an automated support ticket generated in case of conditions such as battery recall for certain device model, battery replacement if the battery is in warranty (e.g., as shown in warranty status 670), inform out of warranty users via reports or emails, or the like. Thus, examples described herein may generate and send reports of the battery health to client device 612 via an email, so that a user can take a necessary action.

The above-described examples are for the purpose of illustration. Although the above examples have been described in conjunction with example implementations thereof, numerous modifications may be possible without materially departing from the teachings of the subject matter described herein. Other substitutions, modifications, and changes may be made without departing from the spirit of the subject matter. Also, the features disclosed in this specification (including any accompanying claims, abstract, and drawings), and/or any method or process so disclosed, may be combined in any combination, except combinations where some of such features are mutually exclusive.

The terms “include,” “have,” and variations thereof, as used herein, have the same meaning as the term “comprise” or appropriate variation thereof. Furthermore, the term “based on”, as used herein, means “based at least in part on.” Thus, a feature that is described as based on some stimulus can be based on the stimulus or a combination of stimuli including the stimulus. In addition, the terms “first” and “second” are used to identify individual elements and may not meant to designate an order or number of those elements.

The present description has been shown and described with reference to the foregoing examples. It is understood, however, that other forms, details, and examples can be made without departing from the spirit and scope of the present subject matter that is defined in the following claims.

What is claimed is:

1. A server comprising:
a receiving unit to obtain a set of battery attributes associated with a battery of a client device;
a prediction unit to predict a battery condition by applying at least one first machine learning model to the set of battery attributes, wherein the battery condition comprises battery swelling, battery memory effect, battery performance degradation, or any combination thereof; and
a recommendation unit to apply a second machine learning model to the predicted battery condition to:
predict a remaining life of the battery; and
recommend an action to be performed based on the predicted remaining life of the battery.

2. The server of claim 1, wherein the recommendation unit is to:
retrieve device information associated with the client device;
retrieve a domain expert feed corresponding to the battery from a knowledge base; and
predict the remaining life of the battery by applying the second machine learning model to the device information, the predicted battery condition, and the domain expert feed.

3. The server of claim 1, wherein the recommended action comprises:
a remedy to manage a lifecycle, a swell rate, and/or a runtime of the battery based on the predicted remaining life; or
a replacement or upgradation of the battery based on the predicted remaining life.

4. The server of claim 1, wherein the recommendation unit is to:
generate an analytical report, on a dashboard of a user interface, including a visualization of analytic or summary information related to the battery swelling, the battery memory effect, the battery performance degradation, the remaining life of the battery, an expected battery life based on the recommend action, or any combination thereof.

5. The server of claim 1, wherein the at least one first machine learning model is trained on input data using machine learning and data mining methods to predict battery swelling, battery memory effect, and/or battery performance degradation, and wherein the input data is selected from a set of time-series historical battery attributes associated with a plurality of batteries.

6. A non-transitory computer-readable storage medium encoded with instructions that, when executed by a processor of a server, cause the processor to:
obtain a set of battery attributes associated with a battery of a client device;
predict battery swelling by applying a first machine learning model to a first subset of the battery attributes;
predict battery memory effect by applying a second machine learning model to a second subset of the battery attributes;
predict battery performance degradation by applying a third machine learning model to a third subset of the battery attributes;
predict a remaining life of the battery by applying a fourth machine learning model to the predicted battery swelling, battery memory effect, and battery performance degradation; and
send a notification including a recommendation to the client device based on the predicted remaining life.

7. The non-transitory machine-readable storage medium of claim 6, wherein the set of battery attributes is classified into the first subset, the second subset, and the third subset based on properties and/or characteristics of the battery attributes.

8. The non-transitory machine-readable storage medium of claim 6, wherein the first machine learning model, the second machine learning model, and the third machine learning model are trained on input data using machine learning and data mining methods to predict battery swelling, battery memory effect, and battery performance degradation, respectively, and wherein the input data is selected from a set of time-series historical battery attributes associated with a plurality of batteries.

9. The non-transitory machine-readable storage medium of claim 8, wherein the fourth machine learning model is trained on input data using the machine learning and the data mining methods to predict remaining life of the battery, and wherein the input data comprises the battery swelling, the battery memory effect, and the battery performance degradation predicted using the time-series historical battery attributes, device information associated with the plurality of batteries, and domain expert feeds.

10. The non-transitory machine-readable storage medium of claim 6, wherein instructions to predict the battery swelling, the battery memory effect, and the battery performance degradation comprise instructions to:
extract at least one first feature vector, at least one second feature vector, and at least one third feature vector from the first subset, the second subset, and the third subset, respectively;
assign a weightage to each of the at least one first feature vector, at least one second feature vector, and at least one third feature vector; and
predict the battery swelling, the battery memory effect, and the battery performance degradation by inputting the at least one first feature vector, at least one second feature vector, and at least one third feature vector and associated weightage into the first machine learning model, second machine learning model, and third machine learning model, respectively, wherein the battery swelling, the battery memory effect, and the battery performance degradation are predicted based on corresponding benchmark data.

11. The non-transitory machine-readable storage medium of claim 6, wherein instructions to predict the remaining life of the battery comprise instructions to:
extract a feature vector by combining the predicted battery swelling, the predicted battery memory effect, and the predicted battery performance degradation; and
predict the remaining life of the battery by inputting the feature vector, a domain expert feed, and device information of the client device into the fourth machine learning model.

12. A non-transitory computer-readable storage medium encoded with instructions that, when executed by a processor of a server, cause the processor to:
obtain time-series historical battery attributes of batteries;
build a first set of machine learning models with the time-series historical battery attributes to predict battery conditions, wherein the battery conditions comprise battery swelling, battery memory effect, and/or battery performance degradation;
build a second machine learning model with the predicted battery conditions and domain expert feeds to predict remaining life of the batteries and generate remediation actions;
obtain a set of battery attributes associated with a battery of a client device;
apply the first set of machine learning models to predict a battery condition of the battery; and
apply the second machine learning model to the battery condition and an expert feed to predict a remaining life of the battery and send a remediation action based on the remaining life.

13. The non-transitory computer-readable storage medium of claim 12, further comprising instructions that, when executed by the processor, cause the processor to:
prior to building the first set of machine learning models, pre-process the time-series historical battery attributes by:
creating a dataset with a plurality of features based on the time-series historical battery attributes;
cleansing and/or imputing the dataset; and
removing collinear and zero importance features from the cleansed and imputed dataset.

14. The non-transitory computer-readable storage medium of claim 12, wherein instructions to build the first set of machine learning models comprise instructions to:
classify the time-series historical battery attributes into a first subset, a second subset, and a third subset based on properties and/or characteristics of the battery attributes;
train, validate, and test a swelling prediction model using the first subset to predict the battery swelling of the batteries;
train, validate, and test a memory prediction model using the second subset to predict the battery memory effect of the batteries; and
train, validate, and test a performance prediction model using the third subset to predict the battery performance degradation of the batteries.

15. The non-transitory computer-readable storage medium of claim 12, wherein instructions to build the second machine learning model comprise instructions to:
train, validate, and test the second machine learning model using an outcome of the first set of machine learning models and the expert feeds to predict the remaining life of the batteries and generate the remediation actions.
